(19) United States
(12) Patent Application Publication
(10) Pub. No.: US 2026/0223723 A1
(43) Pub. Date: Jul. 30, 2026

(54) Electric Circuit Body, Power Conversion Device, and Method for Manufacturing Electric Circuit Body

(71) Applicant: Astemo, Ltd., Chiyoda-ku, Tokyo (JP)

(72) Inventors: Nobutake TSUYUNO, Tokyo (JP); Eiichi IDE, Tokyo (JP); Takahiro SHIMURA, Hitachinaka-shi, Ibaraki (JP)

(21) Appl. No.: 19/159,137

(22) PCT Filed: Apr. 16, 2024
(86) PCT No.: PCT/JP2024/015196

§ 371 Date: Aug. 22, 2025

(30) Foreign Application Priority Data
May 19, 2023 (JP) 2023-083286

(51) Int. Cl. H10W 74/10; H10W 40/00; H10W 40/60; H10W 74/01

(52) U.S. Cl. CPC H10W 74/127; H10W 40/037; H10W 40/611; H10W 74/016

(57) ABSTRACT

An electric circuit body includes: a semiconductor module that includes a semiconductor element sealed with a sealing material and that has a heat dissipation surface on at least one surface, the heat dissipation surface dissipating heat generated by the semiconductor element; a cooling member disposed counter to the heat dissipation surface of the semiconductor module, the cooling member cooling the semiconductor element that generates heat; and a fixing member buried in the sealing material of the semiconductor module, the fixing member restricting movement of the cooling member in the direction of separating away from the semiconductor module. The fixing member includes a buried part buried in the sealing material, and a fixing part inserted into the cooling member to fix the cooling member. At a boundary between the buried part and the fixing part, the buried part has a margin part encircling the outer periphery of the fixing part and exposed from the surface of the sealing material.

### TECHNICAL FIELD

The present invention relates to an electric circuit body, a power conversion device, and a method for manufacturing an electric circuit body.

### BACKGROUND ART

A power conversion device that converts DC power into AC power and vice versa by switching operation of semiconductor elements offers high conversion efficiency and is therefore widely used for consumer applications, in-vehicle equipment, railway equipment, electrical substation equipment, and the like. These semiconductor elements generate heat as a result of their switching operations. Therefore, in a semiconductor module having semiconductor elements built therein, cooling members that cool the heat-generating semiconductor elements are disposed counter to the semiconductor module and are fixed to the semiconductor module by fixing members.

PTL 1 discloses a semiconductor device including a package substrate on which a semiconductor chip is mounted, a sealing resin layer that is formed on the package substrate to seal the periphery of the semiconductor chip, and a fixing member that has one end buried in the sealing resin layer and that fixes another component in such a way as to pinch the semiconductor chip on a side of the package substrate on which semiconductor chip is mounted.

### CITATION LIST

### Patent Literature

PTL 1: JP 2007-109794 A

### SUMMARY OF INVENTION

### Technical Problem

As in the device described in PTL 1, it is necessary that the fixing member buried in the sealing material of the semiconductor module be projected from the semiconductor module. This case, however, poses a problem that the sealing material flows out in the vicinity of the fixing member.

### Solution to Problem

An electric circuit body according to the present invention includes: a semiconductor module that includes a semiconductor element sealed with a sealing material and that has a heat dissipation surface on at least one surface, the heat dissipation surface dissipating heat generated by the semiconductor element; a cooling member disposed counter to the heat dissipation surface of the semiconductor module, the cooling member cooling the semiconductor element that generates heat; and a fixing member buried in the sealing material of the semiconductor module, the fixing member restricting movement of the cooling member in a direction of separating away from the semiconductor module. The fixing member includes a buried part buried in the sealing material, and a fixing part inserted into the cooling member to fix the cooling member. At a boundary between the buried part and the fixing part, the buried part has a margin part encircling the outer periphery of the fixing part and exposed from the surface of the sealing material.

A method for manufacturing an electric circuit body according to the present invention is a method for manufacturing an electric circuit body which includes a semiconductor element, a cooling member that cools the semiconductor element that generates heat, and a fixing member that fixes the cooling member and in which the semiconductor element and the fixing member are sealed with a sealing material. The fixing member includes a buried part buried in the sealing material, and a fixing part inserted into the cooling member to fix the cooling member. At a boundary between the buried part and the fixing part, the buried part has a margin part encircling the outer periphery of the fixing part and exposed from the surface of the sealing material. The method includes: a process of setting a circuit body including the semiconductor element and the fixing member in a mold, bringing the mold into close contact with the margin part of the fixing member, and then injecting the sealing material into the mold to manufacture a semiconductor module; and a process of fixing the cooling member to the semiconductor module by the fixing member after the sealing material cures.

### Advantageous Effects of Invention

According to the present invention, outflow of the sealing material in the vicinity of the fixing member can be prevented.

### BRIEF DESCRIPTION OF DRAWINGS

FIG. 1 is a plan view of an electric circuit body.

FIG. 2(a) and 2(b) are cross-sectional views of the electric circuit body.

FIG. 3 is a cross-sectional perspective view of the electric circuit body taken along a line Y-Y.

FIG. 4 is a cross-sectional perspective view of the electric circuit body taken along a line X-X.

FIG. 5 is a semi-transparent plan view of a semiconductor module.

FIG. 6 is a circuit diagram of the semiconductor module.

FIG. 7(a) to 7(c) depict a process of manufacturing the semiconductor module.

FIG. 8(a) to 8(c) depict a process of fixing a cooling member to the semiconductor module.

FIG. 9 is a cross-sectional view for explaining a method for manufacturing an electric circuit body of a first modification.

FIG. 10 is a plan view of an electric circuit body of a comparative example.

FIG. 11 is a cross-sectional view of an electric circuit body of a second modification.

FIG. 12(a) and 12(b) depict a process of manufacturing a semiconductor module of the second modification.

FIG. 13(a) to 13(c) depict a process of fixing the cooling member to the semiconductor module of the second modification.

FIG. 14 is a cross-sectional view of an electric circuit body of a third modification.

FIG. 15 is a cross-sectional view of an electric circuit body of a fourth modification.

FIG. 16 is a cross-sectional view of an electric circuit body of a fifth modification.

FIG. 17 is a semi-transparent plan view of a semiconductor module of a sixth modification.

FIG. 18 is a circuit diagram of a power conversion device using semiconductor modules.

FIG. 19 is an external perspective view of the power conversion device.

FIG. 20 is a cross-sectional perspective view of the power conversion device taken along a line XV-XV.

### DESCRIPTION OF EMBODIMENTS

Embodiments of the present invention will hereinafter be described with reference to the drawings. The following description and drawings are exemplary ones for explanation of the present invention, and, to make the explanation clear, are omitted or simplified when necessary. The present invention can be implemented in various forms different from embodiments described herein. Unless otherwise specified, each constituent element of a single form and that of a plural form are both applicable.

Positions, sizes, shapes, ranges, and the like of constituent elements shown in the drawings may not represent actual positions, sizes, shapes, ranges, and the like. This is to facilitate understanding of the invention. The present invention, therefore, is not necessarily limited by positions, sizes, shapes, ranges, and the like indicated in the drawings.

When a plurality of constituent elements that are entirely identical or identical in function with each other are present, such constituent elements may be denoted by the same reference sign with different subscripts attached thereto. When distinguishing these constituent elements from each other is unnecessary, however, the constituent elements may be described with their subscripts removed.

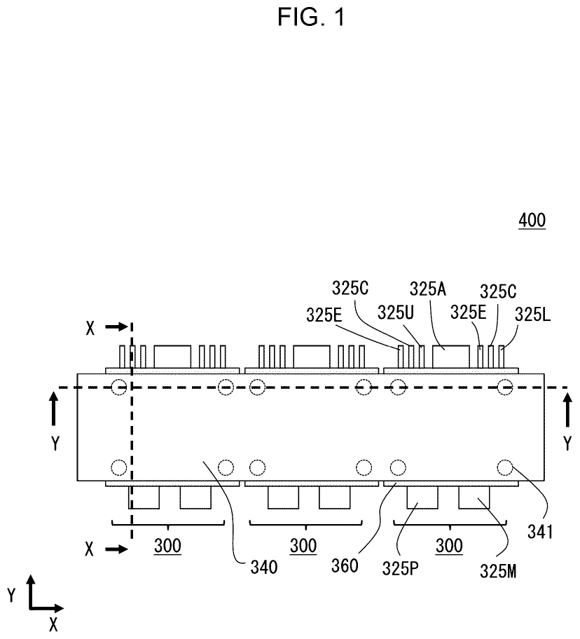

FIG. 1 is a plan view of an electric circuit body 400 according to an embodiment of the present invention.

The electric circuit body 400 includes semiconductor modules 300, a cooling member 340, and fixing members 341. In the example of FIG. 1, the electric circuit body 400 includes three semiconductor modules 300 arranged in parallel.

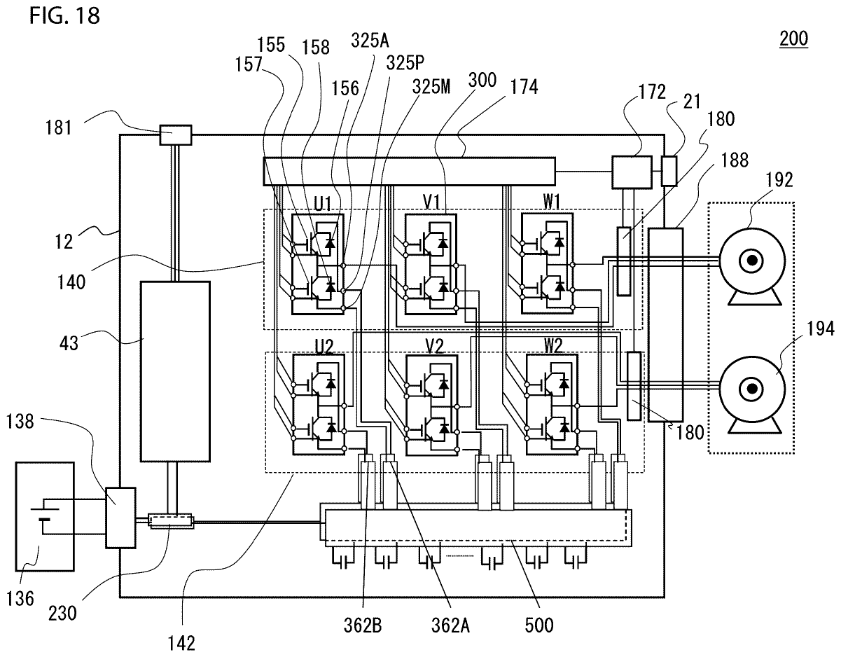

Each semiconductor module 300 has semiconductor elements 155 and 157 sealed with a sealing material 360 and built in the semiconductor module 300. Both surfaces of the semiconductor module 300 dissipate heat generated by switching operations of the semiconductor elements 155 and 157. Further, the semiconductor module 300 has terminals connected to the semiconductor elements 155 and 157 and these terminals are led out from the sealing material 360 on side surfaces of the semiconductor module 300. These terminals are power terminals through which a large current flows, such as a positive electrode side terminal 325P and a negative electrode side terminal 325M that are connected to a capacitor module 500 (see FIG. 18) of a DC circuit and an AC side terminal 325A connected to motor generators 192 and 194 (see FIG. 18) of an AC circuit.

The terminals led out from the sealing material 360 on the side surfaces of the semiconductor module 300 also include a lower arm gate terminal 325L, a collector sense terminal 325C, an emitter sense terminal 325E, and an upper arm gate terminal 325U. These terminals led out from the semiconductor module 300 are connected to wiring lines, such as wiring patterns of a substrate (not illustrated). The electric circuit body 400 including three semiconductor modules 300 arranged in parallel functions as a power conversion device 200 (see FIG. 18) that converts DC power into AC power and vice versa by switching operations of the semiconductor elements 155 and 157. The number of semiconductor modules 300 included in the electric circuit body 400 is not limited to 3, and is determined arbitrarily according to various forms of the electric circuit body 400.

The cooling member 340 is disposed counter to the semiconductor module 300, and cools the semiconductor elements 155 and 157 that generate heat by their switching operations. Specifically, the cooling member 340 has a channel formed inside thereof, the channel allowing a refrigerant to flow therethrough, and, by the refrigerant flowing through the channel, cools the semiconductor elements 155 and 157 that generate heat. As the refrigerant, water, an antifreeze liquid created by mixing water with ethylene glycol, or the like is used. It is desirable that the cooling member 340 be an aluminum-based member having high thermal conductivity and a light weight. The cooling member 340 is fabricated by extrusion molding, forging, brazing, or the like.

The fixing members 341 are buried in the sealing material 360 of the semiconductor module 300, and restrict movement of the cooling member 340 in the direction of separating away from the semiconductor module 300. In the example shown in FIG. 1, the fixing members 341 are arranged at four corners of each semiconductor module 300, respectively. The configuration of each fixing member 341 will be described later.

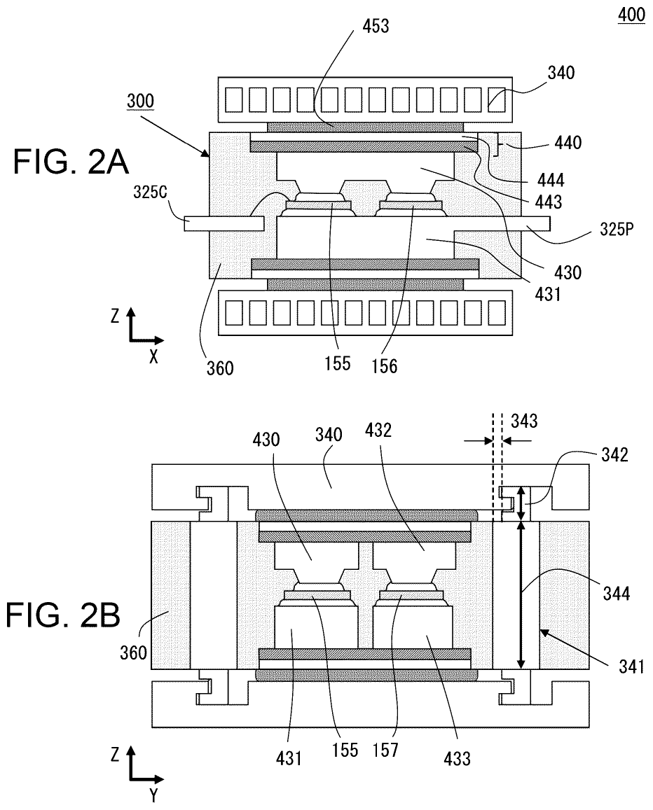

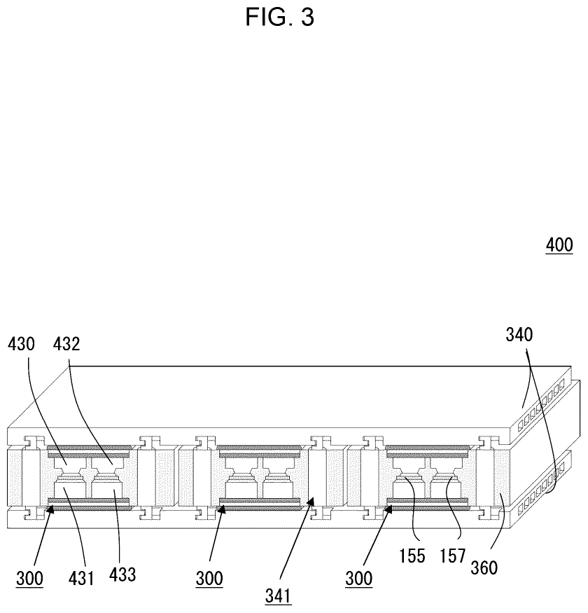

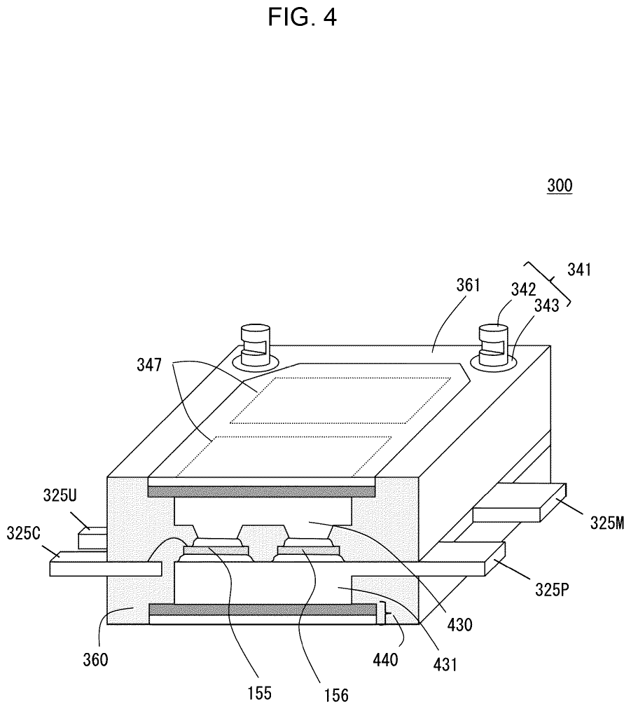

FIG. 2(a) and 2(b) are cross-sectional views of the electric circuit body 400. FIG. 2(a) is a cross-sectional view of the electric circuit body 400 of FIG. 1 that is taken along a line X-X. FIG. ) is a cross-sectional view of one semiconductor module 300 that is taken along a line Y-Y on the electric circuit body 400 shown in FIG. 1. FIG. 3 is a cross-sectional perspective view of the electric circuit body 400 of FIG. 1 that is taken along the line Y-Y. FIG. 4 is a cross-sectional perspective view of the electric circuit body 400 of FIG. 1 that is taken along the line X-X, showing the semiconductor module 300 from which the cooling member 340 is removed.

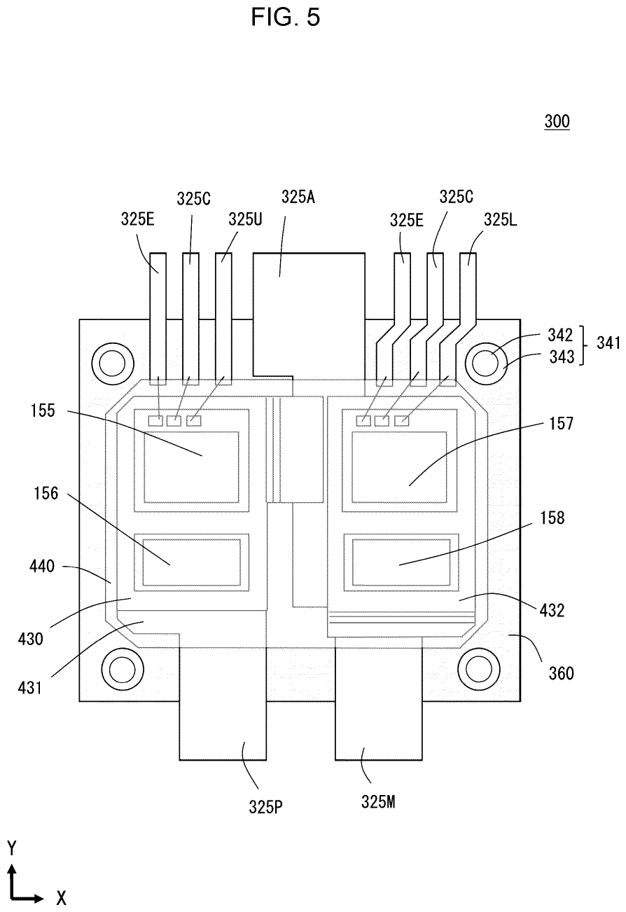

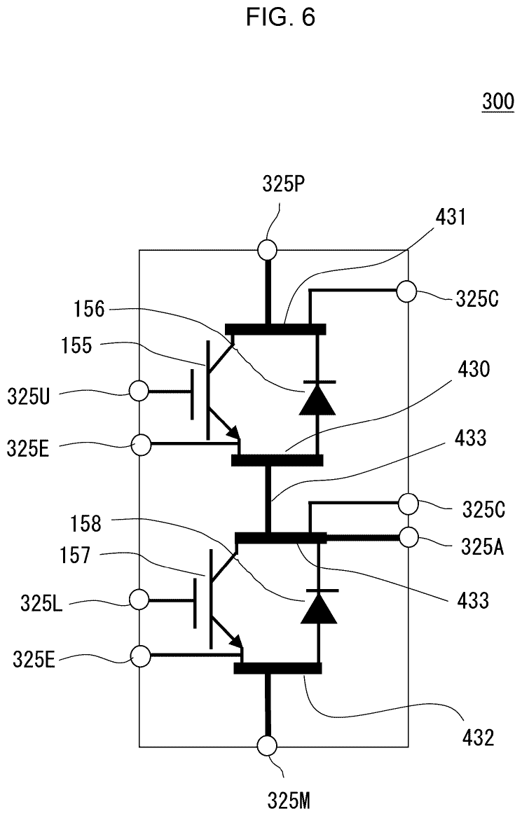

As shown in FIG. 2(a), an active element 155 and a diode 156 are provided as first semiconductor elements forming an upper arm circuit of the power conversion device 200 (see FIGS. 5 and 6 to be referred to later.). As an active element, Si, SiC, GaN, GaO, C, or the like can be used. When a body diode of the active element 155 is used, a separate diode may be dispensed with. As shown in FIG. 2(b) and 3, the collector side of the first semiconductor element 155 is joined to a second conductor plate 431. For this joining, solder or a sintered metal may be used. A first conductor plate 430 is joined to the emitter side of the first semiconductor element 155.

As shown in FIG. 2(b) and 3, an active element 157 and a diode 158 are provided as second semiconductor elements forming a lower arm circuit (see FIGS. 5 and 6 to be referred to later.) . The collector side of the second semiconductor element 157 is joined to a fourth conductor plate 433. A third conductor plate 432 is joined to the emitter side of the second semiconductor element 157.

The conductor plates 430, 431, 432, and 433 are not limited to a specific material, and any material with high electrical conductivity and thermal conductivity may be used as the conductor plates 430, 431, 432, and 433. It is nevertheless desirable to use a metal-based material, such as a copper-based or aluminum-based material, or a composite material made of a metal-based material and diamond, carbon, ceramic, or the like offering high heat conductivity. These materials may be used in their single form, but, to improve their joining to solder or a sintered metal, may be plated with Ni, Ag, or the like.

As shown in FIG. 2(a), 2(b), 3, and 4, in addition to their role of conducting current, the conductor plates 430, 431, 432, and 433 play another role of heat transfer members that transfer heat generated by the semiconductor elements 155, 156, 157, and 158 to the cooling member 340. Surfaces of conductor plates 430, 431, 432, and 433 that are opposite to surfaces joined to the semiconductor elements 155, 156, 157, and 158 serve as heat dissipation surfaces of the conductor plates 430, 431, 432, and 433. Because there is a potential difference between the conductor plates 430, 431, 432, and 433 and the cooling member 340, an insulating sheet 440 is disposed between the heat dissipation surfaces and the cooling member 340.

The insulating sheet 440 is formed by stacking a resin insulating layer 443 and a surface conductor layer 444. The resin insulating layer 443 has its one surface covering the conductor plates 430, 431, 432, and 433 and is bonded to the heat dissipation surfaces of the conductor plates 430, 431, 432, and 433. The resin insulating layer 443 is not limited to a specific material, and any material adhesive to the conductor plates 430, 431, 432, and 433 can be used as the resin insulating layer 443. It is nevertheless desirable to use an epoxy resin-based resin insulating layer dispersed with a powdery inorganic filler. This is because the epoxy resin-based resin insulating layer offers fine balance between adhesion and heat dissipation. The surface conductor layer 444 is bonded to the other surface of the resin insulating layer 443, and is exposed on the surface of the semiconductor module 300, where the surface conductor layer 444 is in contact with a heat conduction member 453, which will be described later. The surface conductor layer 444 is, for example, a metal foil.

The insulating sheet 440 is cured simultaneously together with the sealing material 360 in a transfer molding process. When the insulating sheet 440 is mounted to a mold in the transfer molding process, to prevent adhesion of the insulating sheet 440 to the mold, a release sheet or the surface conductor layer 444 is disposed on a surface where the insulating sheet 440 and the mold come in contact with each other. Because the release sheet has poor thermal conductivity, a process of peeling the release sheet after transfer molding is required. In the case of using the surface conductor layer 444, such as a metal foil, however, by selecting a copper-based or aluminum-based metal with high thermal conductivity as the surface conductor layer 444, the surface conductor layer 444 can be used without peeling it after transfer molding.

The semiconductor elements 155, 156, 157, and 158 and the conductor plates 430, 431, 432, and 433 are sealed with the sealing material 360 by transfer molding to make up the semiconductor module 300. The cooling member 340 is disposed on both surfaces of the semiconductor module 300, and is fixed to the semiconductor module 300 by the fixing members 341. In this embodiment and modifications that will be described later, the electric circuit body 400 having the cooling member 340 disposed on both surfaces of the semiconductor module 300 will be described. However, the electric circuit body 400 may have the cooling member 340 disposed on one surface of the semiconductor module 300. In the latter case, a housing and an attachment member are disposed on the other surface of the semiconductor module 300, and the other surface of the semiconductor module 300 is fixed to the housing and the attachment member by the fixing members 341.

The heat conduction member 453 is disposed between semiconductor module 300 and cooling member 340 to reduce contact thermal resistance. As the heat conduction member 453, grease, gel grease, a phase change sheet, or the like that shows fluidity at normal temperature or high temperature can be used. To ensure workability and long-term reliability, however, using a curable heat conduction material that retains fluidity when uncured and that loses fluidity after being cured is desirable. The curable heat conduction member 453 has an advantage that when it is applied, its low viscosity offers better workability and that its curing improves mechanical properties. Curing methods to use include thermal curing, moisture curing, and ultraviolet curing, among which thermal curing is the desirable one for allowing the heat conduction member 453 to cure to its deep inner part.

Each fixing member 341 is buried in the sealing material 360 of the semiconductor module 300, and is composed of a buried part 344 buried in the sealing material 360, margin parts 343 each exposed on a surface of the sealing material 360, and fixing parts 342 protruding from the sealing material 360, as shown in FIG. 2(b). That is, the fixing member 341 penetrates the semiconductor module 300 in the direction of its thickness, and has the margin parts 343 formed respectively on both ends of the fixing member 341. Details of the margin parts 343 will be described later. Each fixing part 342 of the fixing member 341 protruding from the sealing material 360 is inserted into the cooling member 340 and is mechanically coupled by engagement, screwing, or the like. This fixes the cooling member 340 to the semiconductor module 300. In the examples shown in FIG. 2(b) and 4, a notch is formed on the fixing part 342 of the fixing member 341 while a protrusion to be engaged with the notch is formed on the cooling member 340, and the notch of the fixing part 342 of the fixing member 341 is engaged with the protrusion of the cooling member 340 by translating the cooling member 340 along the surface of the semiconductor module 300.

As shown in FIG. 2(b) and 4, the fixing members 341 are provided at four corners of the semiconductor module 300, respectively, and each has the margin part 343 exposed in such a way as to be flush with a surface 361 of the sealing material 360 of the semiconductor module 300, and the fixing part 342 protruding from the surface 361 of the sealing material 360 of the semiconductor module 300. That is, the fixing member 341 is composed of the buried part 344 buried in the sealing material 360, and the fixing part 342 inserted into the cooling member 340 to fix the cooling member 340, and at a boundary between the buried part 344 and the fixing part 342, the buried part 344 has the margin part 343 that encircles the outer periphery of the fixing part 342 and that is exposed from the surface 361 of the sealing material 360. The margin part 343 and the surface 361 of the sealing material 360 of the semiconductor module 300 are on the same plane.

FIG. 5 is a semi-transparent plan view of the semiconductor module 300. FIG. 6 is a circuit diagram of the semiconductor module 300.

As shown in FIGS. 5 and 6, the positive electrode side terminal 325P extends out from the collector side of the upper arm circuit, and is connected to the positive electrode side of a battery or a capacitor. The upper arm gate terminal 325U extends out from the gate of the active element 155 of the upper arm circuit. The negative electrode side terminal 325M extends out from the emitter side of the lower arm circuit, and is connected to the negative electrode side of the battery or the capacitor or to GND. The lower arm gate terminal 325L extends out from the gate of the active element 157 of the lower arm circuit. The AC side terminal 325A extends out from the collector side of the lower arm circuit, and is connected to a motor. When a neutral point is grounded, the lower arm circuit is connected not to GND but to the negative electrode side of the capacitor.

The emitter sense terminal 325E of the upper arm extends out from the emitter of the active element 155 of the upper arm circuit, and the emitter sense terminal 325E of the lower arm extends out from the emitter of the active element 157 of the lower arm circuit. The collector sense terminal 325C of the upper arm extends out from the collector of the active element 155 of the upper arm circuit, and the collector sense terminal 325C of the lower arm extends out from the collector of the active element 157 of the lower arm circuit.

The conductor plate (upper arm circuit emitter side) 430 is disposed above the active element 155 and the diode 156 of the semiconductor element (upper arm circuit), while the conductor plate (upper arm circuit collector side) 431 is disposed below the same. The conductor plate (lower arm circuit emitter side) 432 is disposed above the active element 157 and the diode 158 of the semiconductor element (lower arm circuit), while the conductor plate (lower arm circuit collector side) 433 is disposed below the same.

The semiconductor module 300 of this embodiment is of a 2-in-1 structure in which two arm circuits, i.e., the upper arm circuit and the lower arm circuit, are integrated into one module. Besides the 2-in-1 structure, a structure in which a plurality of upper arm circuits and lower arm circuits are integrated into one module may also be used. In this case, the number of output terminals from the semiconductor module 300 can be reduced to miniaturize the semiconductor module 300.

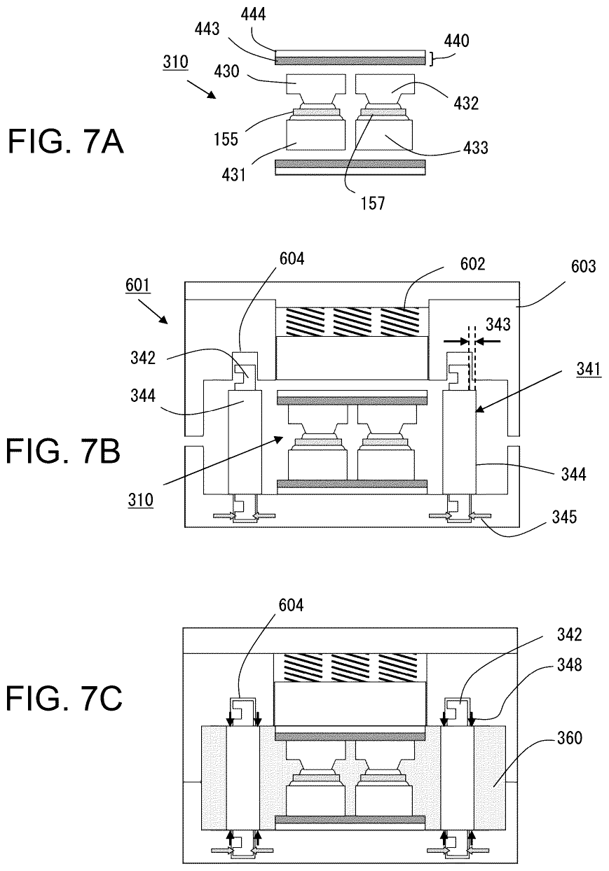

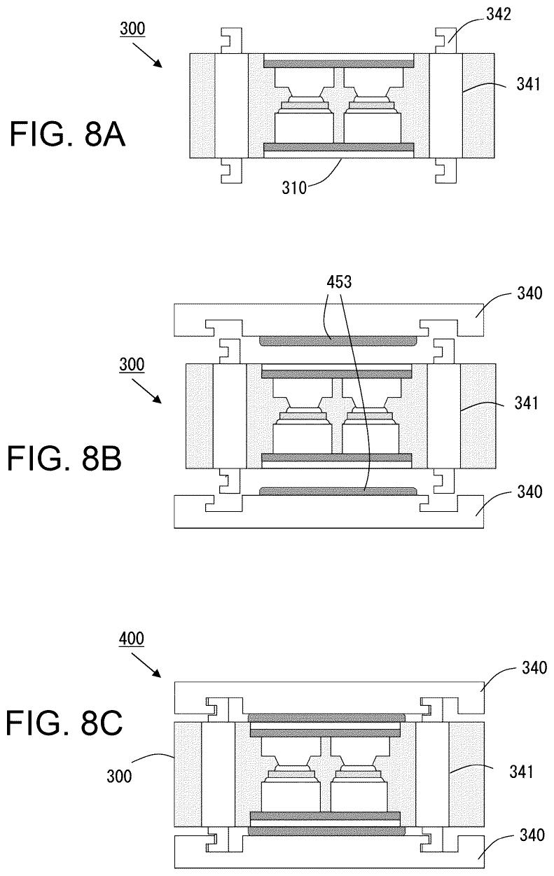

FIG. 7(a) to 7(c) and 8(a) to 8(c) are cross-sectional views for explaining processes in a method for manufacturing the electric circuit body 400. Similar to FIG. 2(b), each of these cross-sectional views is a cross-sectional view of one semiconductor module 300 taken along the line Y-Y.

FIG. 7(a) to 7(c) show a process of setting a circuit body 310 including the semiconductor elements 155 and 156 and the fixing member 341 in the mold 603, bringing the mold 603 into close contact with the margin part 343 of the fixing member 341, and then injecting the sealing material 360 into the mold 603 to manufacture the semiconductor module 300.

FIG. 8(a) to 8(c) show a process of fixing the cooling member 340 to the semiconductor module 300 by the fixing member 341 after the sealing material 360 is cured.

FIG. 7(a) shows a temporary bonding process. The collector side of the semiconductor element 155 and the cathode side of the semiconductor element 156 are connected to the second conductor plate 431, and the gate electrode, the emitter sense electrode, and the collector electrode of the semiconductor element 155 are connected to the gate terminal 325U, the emitter sense terminal 325E, and the collector sense terminal 325C of the upper arm, respectively, by wire bonding. Then, the emitter side of the semiconductor element 155 and the anode side of the semiconductor element 156 are connected to the first conductor plate 430 to manufacture a circuit body 310 on the upper arm side. Similarly, the collector side of the semiconductor element 157 and the cathode side of the semiconductor element 158 are connected to the fourth conductor plate 433, and the gate electrode, the emitter sense electrode, and the collector electrode of the semiconductor element 157 are connected to the gate terminal 325L, the emitter sense terminal 325E, and the collector sense terminal 325C of the lower arm, respectively, by wire bonding.

Then, the emitter side of the semiconductor element 157 and the anode side of the semiconductor element 158 are connected to the third conductor plate 432 to manufacture a circuit body 310 on the lower arm side. Thereafter, the insulating sheet 440 is temporarily bonded to the conductor plates 430 to 433. This temporary bonding refers to temporarily pasting the insulating sheet 440 using its adhesive force under a condition that there is room for curing and bonding of the insulating sheet 440 in the transfer molding process that follows.

FIG. 7(b) to 7(c) show the transfer molding process. A transfer molding device 601 includes a spring 602 incorporated in the mold 603. By this spring 602, even if the height of the circuit body 310 varies, application of an excessive pressure to the semiconductor elements 155 to 158 is prevented. The force of the spring 602 ensures application of a predetermined load. The transfer molding device 601 includes a vacuum degassing mechanism (not illustrated). By vacuum degassing, even if the sealing material 360 made of resin or the like has voids formed therein, the voids can be compressed into small one to improve insulating properties. In addition, by covering the circuit body 310 with a release film (not illustrated), a resin burr's entering a spring drive portion and the like can be prevented.

As shown in FIG. 7(b), the circuit body 310 with the insulating sheet 440 temporarily bonded and the fixing member 341 are set in the mold 603 that is preheated into a constant temperature state of 175° C. In the mold 603, recesses 604 are formed, into each of which the fixing part 342 of the fixing member 341 is inserted. At the boundary between the buried part 344 and the fixing part 342 of the fixing member 341, the recess 604 is larger than the outer periphery of the fixing part 342 and is smaller than the outer periphery of the margin part 343.

Subsequently, as shown in FIG. 7(c), upper and lower molds 603 are clamped. At this time, the spring 602 pressurizes the insulating sheet 440 and the conductor plates 430 to 433, thus bringing the insulating sheet 440 into close contact with the conductor plates 430 to 433. At the same time, the upper and lower molds 603 apply a pressing force 348 to the margin part 343 of the fixing member 341, thus bringing the periphery of the opening of the recess 604 of the mold 603 into close contact with the margin part 343. In this state, the sealing material 360 is injected into the mold 603. As a result, in the vicinity of the fixing part 342 of the fixing member 341, outflow of the sealing material 360 to the fixing part 342 can be prevented, and the buried part 344 of the fixing member 341 can be firmly sealed and fixed in the sealing material 360. Because outflow of the sealing material 360 to the fixing part 342 can be prevented, an additional process or the like of removing the sealing material 360 deposited on the fixing part 342 to expose the fixing part 342 becomes unnecessary.

Thereafter, as shown in FIG. 8(a), the semiconductor module 300 sealed with the sealing material 360 is taken out from the transfer molding device 601, and is subjected to post-curing at 175° C. for 2 hours or more.

Subsequently, as shown in FIG. 8(b), after the sealing material 360 is cured, the cooling member 340 is attached to the semiconductor module 300. Specifically, the heat conduction member 453 is applied to the cooling members 340, and the cooling members 340 are mounted on both surfaces to sandwich the semiconductor module 300 and then are moved along the heat dissipation surfaces to be fitted on the fixing parts 342 such that each protrusion formed on the cooling members 340 is engaged with each notch of the fixing part 342 of the fixing member 341.

Then, as shown in FIG. 8(c), the cooling member 340 is fixed to the semiconductor module 300. The cooling member 340 is thus firmly fixed to the semiconductor module 300 via the heat conduction member 453, by the fixing member 341, to make up the integral structure of the electric circuit body 400. It should be noted that although it is not illustrated, a member that prevents the cooling member 340 from moving along the heat dissipation surface is attached so that the protrusion of the cooling member 340 is not disengaged from the notch of the fixing part 342.

The fixing member 341 will then be described with reference to FIG. 2(b) and 7(b). The fixing part 342 of the fixing member 341 needs to mechanically fix the cooling member 340 and to withstand stress, such as thermal stress and vibration. For this reason, the diameter o of the fixing part 342 needs to be 2.5 mm or more, and to offer a margin of reliability, the diameter Φ should desirably be 4.5 mm or more. Because an increase in the size of the fixing part 342 results in an increase in the size of the semiconductor module 300, it is desirable that the diameter o of the fixing part 342 be 10 mm or less.

At the boundary between the buried part 344 and the fixing part 342 of the fixing member 341, a relationship between the size of the outer periphery of the fixing part 342 and the size of the outer periphery of the margin part 343 should desirably be represented by a gap described below in order to prevent outflow of the sealing material 360. This gap refers to the distance between the outer periphery of the fixing part 342 and the outer periphery of the margin part 343 at a point at which the distance becomes the shortest. When this gap is 0.5 mm or more, outflow of the sealing material 360 to the fixing part 342 can be prevented in the transfer molding process, in which case, however, resin burrs may be formed on the fixing part 342. It is desirable for this reason that the gap be 1 mm or more. When the margin part 343 increases in size, however, the semiconductor module increases in size. It is therefore desirable that the gap be 10 mm or less.

Materials making up the fixing member 341 include a metal, such as copper or aluminum, fiber reinforced plastics, and ceramic. When the fixing member 341 and the cooling member 340 are electrically connected and grounded, the fixing member 341 should desirably be made of a conductive material. It is desirable that the fixing member 341 be formed into a columnar shape for the reason that considering a direction when mounting the fixing member to the transfer mold is unnecessary. Nevertheless, the fixing member 341 may be of a prismatic shape or other shapes.

When a material of the margin part 343 has hardness lower than the hardness of a material making up the mold 603, the margin part 343 is easily deformed, in which case wear of the mold 603 can be suppressed. When a material of the fixing part 342 has hardness higher than the hardness of the material of the margin part 343, on the other hand, the mechanical strength of fixing part 342 is improved, in which case, even if vibration or thermal stress is applied when the cooling member 340 is fixed, high reliability is maintained.

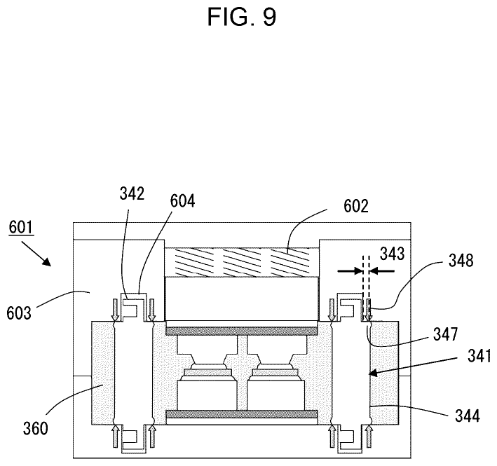

FIG. 9 is a cross-sectional view for explaining a method for manufacturing an electric circuit body 400 of a first modification. Similarly to the explanation of the process of manufacturing the semiconductor module 300 as shown in FIG. 7(c), a cross-sectional view of one semiconductor module 300 that is taken along the line Y-Y is shown. The same parts as shown in FIG. 7(c) are denoted by the same reference signs, and description thereof will be simplified.

In this first modification, a member including the buried part 344 slightly longer than a space formed by the upper and lower molds 603 is used as the fixing member 341. It is desirable that the material of the margin part 343 have hardness lower than the hardness of the material of the mold 603.

As shown in FIG. 9, the upper and lower molds 603 are clamped. At this time, the upper and lower molds 603 apply the pressing force 348 to the fixing member 341, which deforms the margin part 343 toward its outer periphery to create a deformed part 347. As a result, even if the length of the fixing member 341 varies as a result of dimensional irregularities, the margin part 343 and the mold 603 can be brought into close contact with each other. In a mass production process, a component with dimensional irregularities may be used in some cases. By creating the deformed part 347 at the outer periphery of the margin part 343, however, the dimensional irregularities can be absorbed and outflow of the sealing material 360 to the fixing part 342 can be prevented as well.

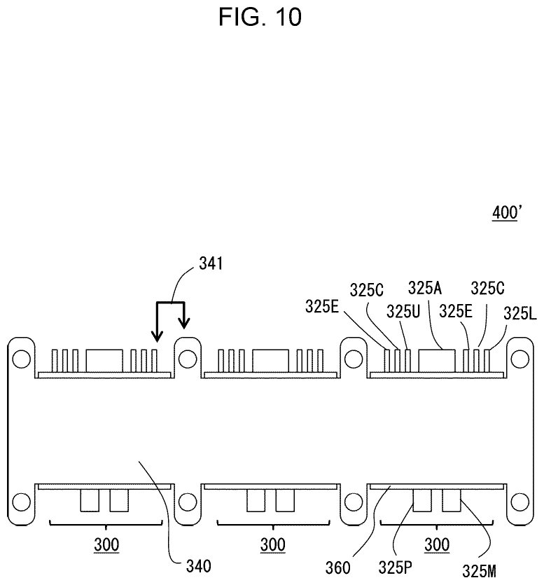

FIG. 10 is a plan view of an electric circuit body 400′ of a comparative example. This comparative example, which is a case where this embodiment is not applied, is an example that is ordinally assumed in a case where the semiconductor module 300 and the cooling member 340 are firmly fixed, and is shown for comparison with this embodiment. The same parts as shown in FIG. 1 are denoted by the same reference signs.

Similar to the electric circuit body 400′ of FIG. 1, the electric circuit body 400′ includes three semiconductor modules 300 arranged in parallel, and the cooling member 340 is fixed to each semiconductor module 300 by the fixing members 341. The fixing members 341 are, however, not buried in the sealing material 360 of each semiconductor module 300 and are each located between adjacent semiconductor modules 300 such that the fixing members 341 sandwich the cooling members 340 on both surfaces.

In general, the cooling member 340 is grounded via the fixing member 341 or the like, and therefore a potential is created between a terminal led out from the semiconductor module 300 and the cooling member 340. In addition, from the viewpoint of cost and mechanical strength, the fixing part 342 should preferably be made of a metal-based material and its potential is equal to the potential of the cooling member 340. Given these facts, it is necessary that an insulation distance be provided between the terminal and the cooling member 340 and between the terminal and the fixing member 341. When a system voltage of an inverter composed of the semiconductor modules 300 becomes a high voltage higher than 400 V currently used for general purposes, e.g., a high voltage equal to or higher than 800 V, a larger insulation distance is required. Besides, the electric circuit body 400′ needs to increase its strength against thermal stress, vibration, and the like. To meet these requirements, as shown in the comparative example of FIG. 10, between adjacent semiconductor modules 300 and outside the semiconductor modules 300, the cooling member 340 is firmly fixed to each semiconductor module 300, using the fixing member 341 provided as screws or the like.

Furthermore, in the case of the system voltage becoming a high voltage equal to or higher than 800 V, an insulation distance corresponding to a potential difference is needed also between different terminals led out from the semiconductor module 300. That is, in the case of a high-voltage inverter running at 800 V or higher, its inter-terminal distance tends to become longer than an inter-terminal distance of an inverter running at 400 V currently used for general purposes. In this case, if the fixing member 341 made of a metal-based material is present near a terminal, it limits a degree of freedom of placement of the terminal, and consequently, because of the need of providing the insulation distance, the size of the electric circuit body 400′ increases.

In contrast with this comparative example, according to this embodiment, the cooling member 340 is fixed by burying the buried part 344 of the fixing member 341 in the sealing material 360 and exposing the fixing part 342 of the fixing member 341 on the surface of the sealing material 360. In this manner, burying the fixing member 341 in the sealing material 360 enhances the insulation between the fixing member 341 and the terminal, and consequently reduces the physical distance between the fixing member 341 and the terminal. In this condition, the cooling member 340 can be firmly fixed by the fixing part 342 of the fixing member 341, the fixing part 342 being exposed on the surface of the sealing material 360. Thus, even when the electric circuit body 400 is applied to a high-voltage inverter, an increase in the size of the inverter can be suppressed.

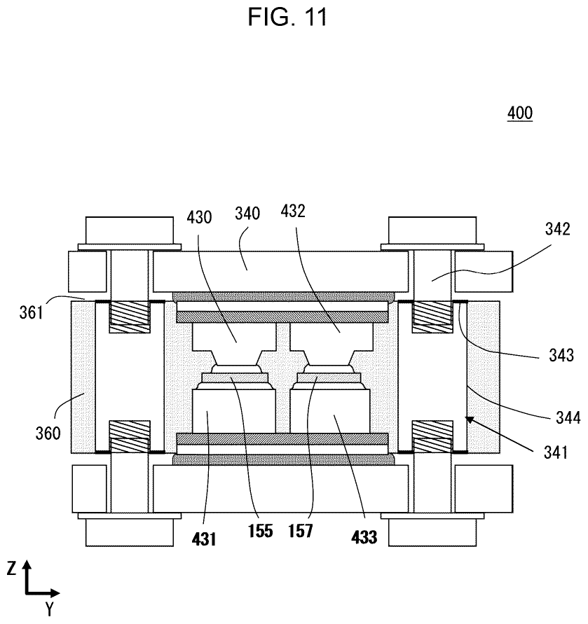

FIG. 11 is a cross-sectional view of an electric circuit body 400 of a second modification. Similar to FIG. 2(b), FIG. 11 is a cross-sectional view of one semiconductor module 300 that is taken along the line Y-Y on the electric circuit body 400 shown in FIG. 1. The same parts as shown in FIG. 2(b) are denoted by the same reference signs, and description thereof will be simplified.

In the second modification, as shown in FIG. 11, the fixing member 341 penetrates the semiconductor module 300 in the direction of its thickness, and the margin part 343 is formed on both ends of the fixing member 341. The margin part 343 is flush with the surface 361 of the sealing material 360 of the semiconductor module 300. The fixing part 342 of fixing member 341 penetrates the cooling member 340, and is composed of a fastening member, such as a screw. The fixing part 342 composed of a fastening member, such as a screw, is fitted into a receiving hole that is formed in the buried part 344 with the cooling member 340 interposed between the fixing part 342 and the buried part 344, to fasten the cooling member 340 to the semiconductor module 300. The margin part 343 is formed on the outer periphery of the receiving hole formed in the buried part 344.

According to the second modification, in the vicinity of the fixing part 342 of the fixing member 341, outflow of the sealing material 360 to the fixing part 342 can be prevented, and the buried part 344 of the fixing member 341 can be firmly sealed and fixed in the sealing material 360. In addition, because the fixing member 341 composed of a fastening member, such as a screw, is used, even if the thickness or the like of the cooling member 340 varies due to dimensional irregularities, fastening the fixing member 341 according to the dimensional irregularities allows the cooling member 340 to be reliably fixed to the semiconductor module 300.

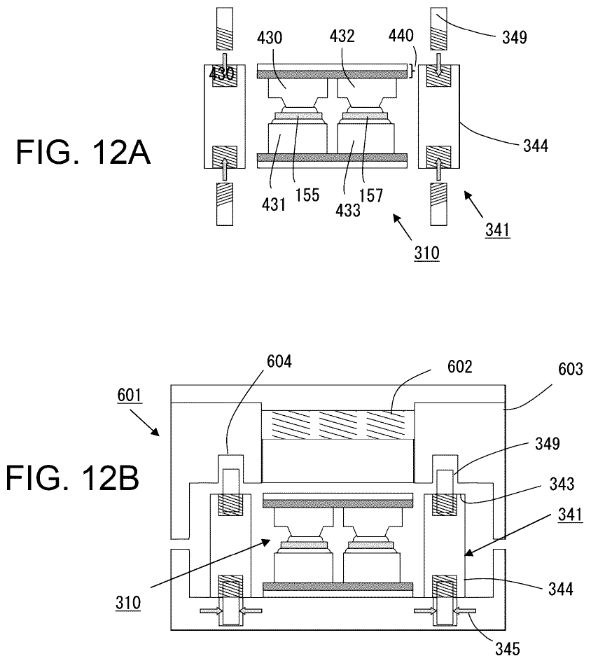

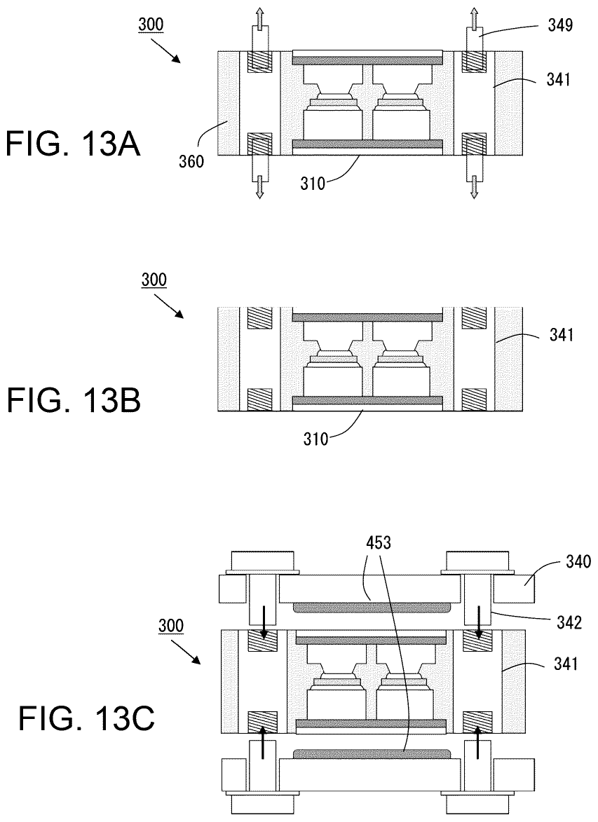

FIG. 12(a) and 12(b) and 13(a) to 13(c) are cross-sectional views for explaining processes in a method for manufacturing the electric circuit body 400 of the second modification. Similar to FIG. 2(b), each of these cross-sectional views is a cross-sectional view of one semiconductor module 300 taken along the line Y-Y.

FIG. 12(a) and 12(b) show a process of manufacturing the semiconductor module 300, and FIG. 13(a) to 13(c) show a process of fixing the cooling member 340 to the semiconductor module 300 by the fixing member 341.

As shown in FIG. 12(a), in the temporary bonding process, the insulating sheet 440 is temporarily bonded to the conductor plates 430 to 433 Then, the fixing member 341 is prepared, and an insertion member 349 for positioning is fitted in the receiving hole formed on the buried part 344 of the fixing member 341.

As shown in FIG. 12(b), in the transfer molding process, the circuit body 310 with the insulating sheet 440 temporarily bonded and the fixing member 341 are set in the mold 603 preheated into the constant temperature state of 175° C. Because the insertion member 349 is fitted to the fixing member 341, the insertion member 349 comes into the recess 604 formed on the mold 603, which allows the fixing member 341 to be held at a given position of the mold 603. The margin part 343 is formed on the outer periphery of the receiving hole formed in the buried part 344.

When the upper and lower molds 603 are clamped, the upper and lower molds 603 apply a pressing force to the margin part 343 of the fixing member 341, which brings the periphery of the opening of the recess 604 of the mold 603 into close contact with the margin part 343. In this state, the sealing material 360 is injected into the mold 603. As a result, in the vicinity of the fixing part 342 of the fixing member 341, outflow of the sealing material 360 to the fixing part 342 can be prevented, and the buried part 344 of the fixing member 341 can be firmly sealed and fixed in the sealing material 360.

Thereafter, a as shown in FIG. 13(a), the semiconductor module 300 sealed with the sealing material 360 is taken out from the transfer molding device 601, and the insertion member 349 is removed. Then, as shown in FIG. 13(b), post-curing is performed at 175° C. for 2 hours or more.

Subsequently, as shown in FIG. 13(c), after the sealing material 360 is cured, the cooling member 340 is attached to the semiconductor module 300. Specifically, the heat conduction member 453 is applied to the cooling member 340, and the fixing part 342 composed of a fastening member, such as a screw, is fitted into the receiving hole formed on the buried part 344 to fasten the cooling member 340 to the semiconductor module 300.

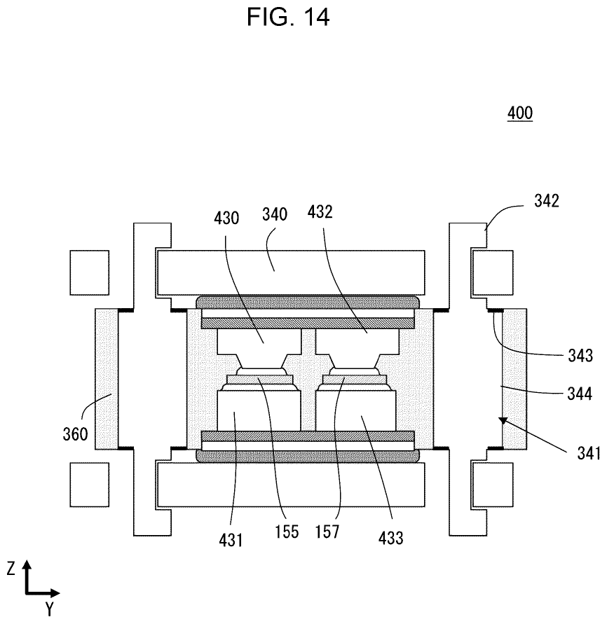

FIG. 14 is a cross-sectional view of the electric circuit body 400 of a third modification. Similar to FIG. 2(b), FIG. 14 is a cross-sectional view of one semiconductor module 300 that is taken along the line Y-Y on the electric circuit body 400 shown in FIG. 1. The same parts as shown in FIG. 2(b) are denoted by the same reference signs, and description thereof will be simplified.

In FIG. 2(b), the fixing part 342 of the fixing member 341 is provided with the notch that is engaged with the protrusion formed on the cooling member 340 so as not to penetrate the cooling member 340. In the third modification, as shown in FIG. 14, the fixing part 342 is provided with a notch by which the fixing part 342 penetrating the cooling member 340 engages with the cooling member 340. Because the cooling member 340 is fixed by using its entire thickness, the cooling member 340 and the semiconductor module 300 can be firmly fixed together. It should be noted that although it is not shown, a member that prevents movement of the cooling member 340 along the heat dissipation surface is attached so that the notch of the fixing part 342 is not disengaged from the cooling member 340.

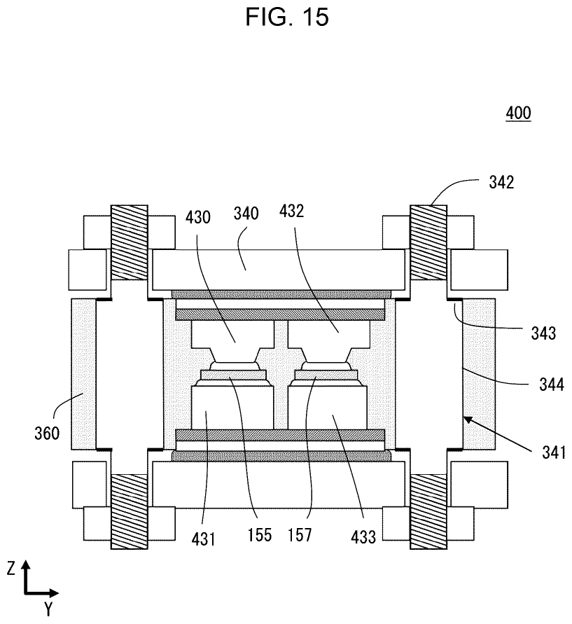

FIG. 15 is a cross-sectional view of an electric circuit body 400 of a fourth modification. Similar to FIG. 2(b), FIG. 15 is a cross-sectional view of one semiconductor module 300 that is taken along the line Y-Y on the electric circuit body 400 shown in FIG. 1. The same parts as shown in FIG. 2(b) are denoted by the same reference signs, and description thereof will be simplified.

In the fourth modification, as shown in FIG. 15, the fixing part 342 of the fixing member 341 penetrates the cooling member 340, and a nut is screwed onto the fixing part 342 having a threaded part formed thereon to fix the cooling member 340. Because the cooling member 340 is fixed by using its entire thickness, the cooling member 340 and the semiconductor module 300 can be firmly fixed together. By using the fixing member 341 formed of a fastening member such as a screw, even if there is a dimensional variation in the cooling member 340 or the like, the cooling member 340 can be reliably fixed to the semiconductor module 300 by fastening according to the dimensional variation.

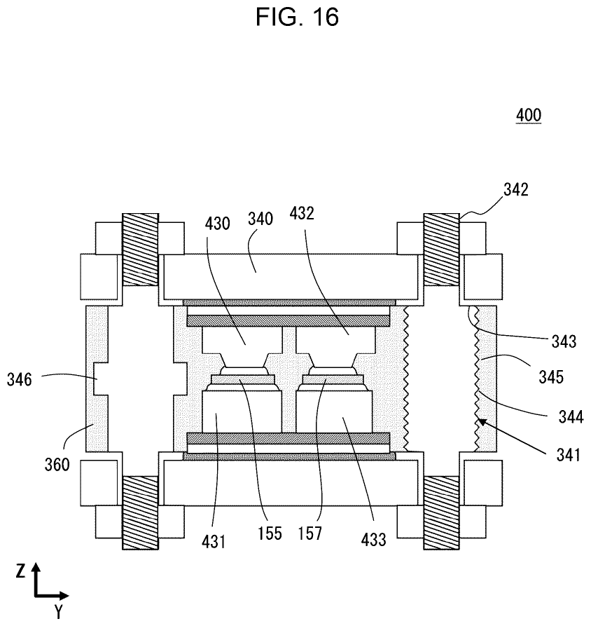

FIG. 16 is a cross-sectional view of an electric circuit body 400 of a fifth modification. Similar to FIG. 2(b), FIG. 16 is a cross-sectional view of one semiconductor module 300 that is taken along the line Y-Y on the electric circuit body 400 shown in FIG. 1. The same parts as shown in FIG. 2(b) are denoted by the same reference signs, and description thereof will be simplified.

In the fifth modification, the outer peripheral surface of the buried part 344 of the fixing member 341 is subjected to a surface treatment for improving adhesion to the sealing material 360. In an example shown in FIG. 16, an uneven shape 345 is formed on the outer peripheral surface of the buried part 344. In another example shown in FIG. 16, a protrusion 346 is formed on the outer peripheral surface of the buried part 344. The outer peripheral surface may be subjected to other types of surface treatments, such as roughening, dimpling, and application of an adhesion imparting agent. In the electric circuit body 400, surface treatments may vary, depending on locations of placement of the fixing member 341 or the like.

Hereinafter, the necessity of the surface treatment shown in the fifth modification will be described. When the cooling member 340 and the semiconductor module 300 are fixed together, ensuring reliable heat dissipation is required. For example, when they are fixed with the fixing part 342 provided as a screw having a diameter Φ of 4 mm, the screw exerts an axial force, which is a pressing force of about 1200 N that is applied to the sealing material 360. When the diameter Φ is 5 mm, a pressing force of about 2000 N is applied to the sealing material 360. This pressing force is a large force. For example, by fixing the front surface and the back surface of the semiconductor module 300 with one fixing member 341, an axial force for fixing the front surface of the semiconductor module 300 and an axial force for fixing the back surface of the semiconductor module 300 are applied to one fixing member 341. This suppresses application of an excessive stress to the sealing material 360. However, there is a case where a force is applied to the sealing material 360 in an attachment process or the like. In the fifth modification, as described above, the surface treatment for adhesion to the sealing material 360 is performed. As a result, adhesive strength between the sealing material 360 and the buried part 344 is improved, and therefore, even if the cooling member 340 and the semiconductor module 300 are fixed together with a strong force, high reliability can be maintained.

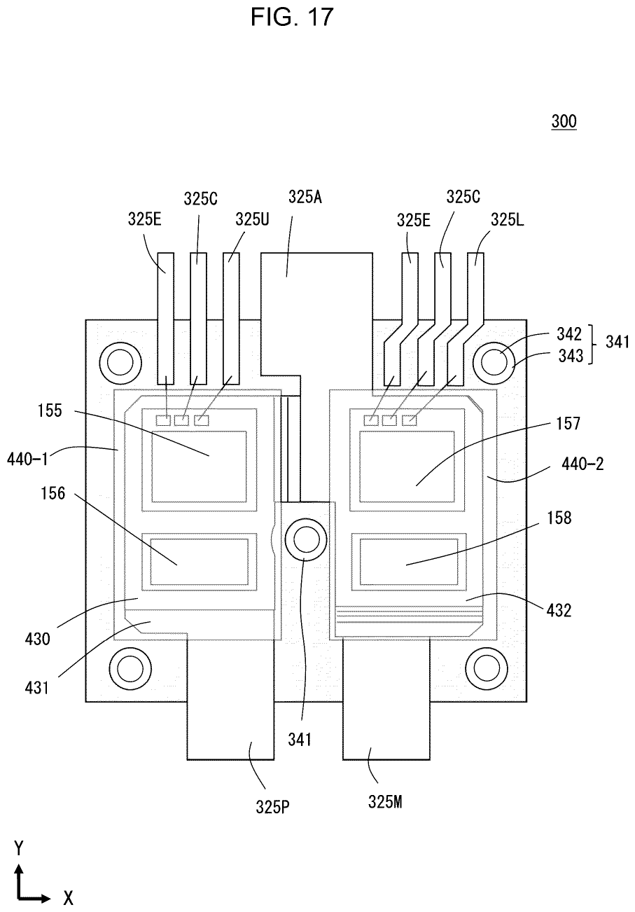

FIG. 17 is a semi-transparent plan view of a semiconductor module 300 of a sixth modification. The same parts as shown in FIG. 5 are denoted by the same reference signs, and description thereof will be simplified.

FIG. 5 shows the example in which the fixing members 341 are provided at four corners of the semiconductor module 300, respectively. In the sixth modification shown in FIG. 17, the fixing member 341 is provided also at the central part of the semiconductor module 300. Specifically, an insulating sheet 440-1 on the upper arm side and an insulating sheet 440-2 on the lower arm side are separated from each other, and the fixing member 341 is provided also at the central part. The insulating sheets 440-1 and 440-2 are separated for the purpose of bringing the margin part 343 of the fixing member 341 provided at the central part into close contact with the periphery of the opening of the recess 604 of the mold 603 in the transfer molding process. Described is an example in which one fixing member 341 is provided at the central part of the semiconductor module 300. However, a plurality of fixing members 341 may be provided at the central part or at other parts, such as central parts of four sides of the semiconductor module 300.

The sixth modification allows the cooling member 340 and the semiconductor module 300 to be fixed uniformly with a strong force, and offers an effect of high reliability.

FIG. 18 is a circuit diagram of a power conversion device 200 using semiconductor modules 300.

The power conversion device 200 includes inverter circuit units 140 and 142, an inverter circuit unit 43 for auxiliary equipment, and a capacitor module 500. The inverter circuit units 140 and 142 each include a plurality of semiconductor modules 300, which are connected to make up a three-phase bridge circuit. When a current capacity is large, more semiconductor modules 300 are additionally connected in parallel, and such parallel connection is made in correspondence to each phase of a three-phase inverter circuit. This deals with a problem of the increasing current capacity. The problem of the increasing current capacity can also be dealt with by parallelly connecting the active elements 155 and 157 and the diodes 156 and 158, which are semiconductor elements incorporated in the semiconductor module 300.

The inverter circuit unit 140 and the inverter circuit unit 142 have the same basic circuit configuration, and, basically, their control methods and operations are also the same. An outline of the circuit operation of the inverter circuit unit 140 and the like is well known, and therefore detailed description of the outline of the circuit operation is omitted.

The upper arm circuit includes the active element 155 for the upper arm and the diode 156 for the upper arm, as switching semiconductor elements, and the lower arm circuit includes the active element 157 for the lower arm and the diode 158 for the lower arm, as switching semiconductor elements. The active elements 155 and 157 receive a drive signal outputted from one or the other of two driver circuits making up a driver circuit 174 and perform a switching operation to convert DC power supplied from a battery 136 into three-phase AC power.

The active element 155 for the upper arm and the active element 157 for the lower arm each have a collector electrode, an emitter electrode, and a gate electrode. The diode 156 for the upper arm and the diode 158 for the lower arm each have two electrodes, i.e., a cathode electrode and an anode electrode. As shown in FIG. 8, the cathode electrodes of the diodes 156 and 158 are electrically connected to the collector electrodes of the active elements 155 and 157, respectively, and the anode electrodes of the same are electrically connected to the emitter electrodes of the active devices 155 and 157, respectively. As a result, at the active element 155 for the upper arm and the active element 157 for the lower arm, the direction of a current flow from the emitter electrode to the collector electrode is a forward direction. The active elements 155 and 157 are, for example, IGBTs.

It should be noted that a metal oxide semiconductor field effect transistor (MOSFET) may be used as the active element, in which case the diode 156 for the upper arm and the diode 158 for the lower arm are unnecessary.

The positive electrode side terminal 325P and the negative electrode side terminal 325M of each upper/lower arm series circuit are connected respectively to DC terminals for capacitor connection of the capacitor module 500. AC power is generated at each connecting part between the upper arm circuit and the lower arm circuit, and a connection part between the upper arm circuit and the lower arm circuit, the connecting part being on each upper/lower arm series circuit, is connected to the AC side terminal 325 A of each semiconductor module 300. AC side terminals 320B of each semiconductor module 300 of each phase are connected respectively to AC output terminals of the power conversion device 200, and generated AC power is supplied to the stator winding of the motor generator 192 or 194.

A control circuit 172 generates a timing signal for controlling timing of switching of the active element 155 for the upper arm and the active element 157 for the lower arm, based on input information from a control device, a sensor (e.g., a current sensor 180), or the like incorporated in a vehicle. Based on a timing signal outputted from the control circuit 172, the driver circuit 174 generates a drive signal that causes the active element 155 for the upper arm and the active element 157 for the lower arm to switch. 181 and 188 denote connectors.

The upper/lower arm series circuit includes a temperature sensor (not illustrated), and temperature information on the upper/lower arm series circuit is inputted to a microcomputer. Voltage information on the DC positive side of the upper/lower arm series circuit is inputted to the microcomputer. Based on these pieces of information, the microcomputer carries out overtemperature detection and overvoltage detection, and when detecting overtemperature or overvoltage, causes all active elements 155 for the upper arm and active elements 157 for the lower arm to stop their switching operations to protect the upper/lower arm series circuits from overtemperature or overvoltage.

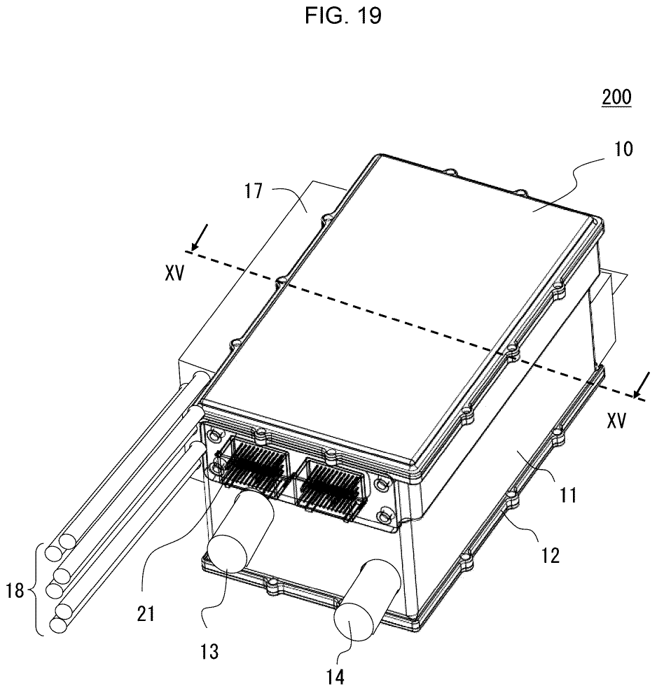

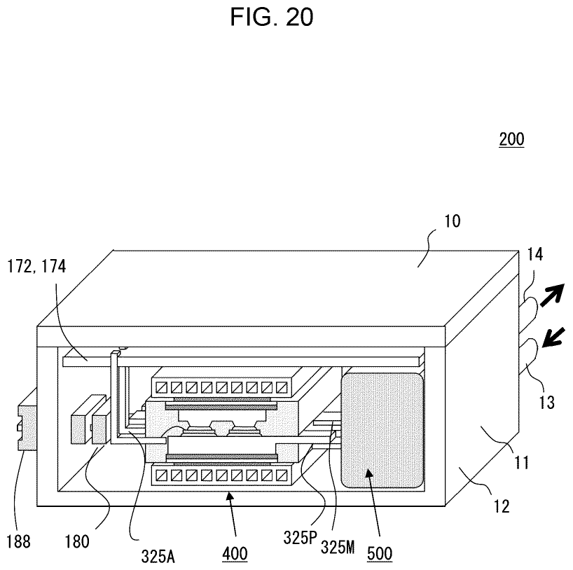

FIG. 19 is an external perspective view of the power conversion device 200 shown in FIG. 18, and FIG. 20 is a cross-sectional perspective view of the power conversion device 200 of FIG. 19 that is taken along a line XV-XV.

The power conversion device 200 includes a housing 12 that is composed of a lower case 11 and an upper case 10 and that is formed into a substantially rectangular parallelepiped shape. Inside the housing 12, the electric circuit body 400, the capacitor module 500, and the like are placed. The electric circuit body 400 has a cooling channel leading to the cooling member 340, and a refrigerant inflow pipe 13 and a refrigerant outflow pipe 14 that communicate with the cooling channel project out from one side surface of the housing. The lower case 11 has an opening on its top side, and the upper case 10 is attached to the lower case 11 in such a way as to close the opening of the lower case 11. The upper case 10 and the lower case 11 are each formed of an aluminum alloy or the like, and are fixed in a state of being sealed against the outside. The upper case 10 and the lower case 11 may be configured into an integral structure. Forming the housing 12 into a simple rectangular parallelepiped shape facilitates attachment of the housing 12 to a vehicle or the like, and makes its production easy as well.

A connector 17 is attached to one side surface of the housing 12 along its longitudinal direction, and AC terminals 18 are connected to the connector 17. Connectors 21 are disposed on the surface from which the refrigerant inflow pipe 13 and the refrigerant outflow pipe 14 are led out.

As shown in FIG. 20, the electric circuit body 400 is placed in the housing 12. The control circuit 172 and the driver circuit 174 are arranged for the electric circuit body 400, and the capacitor module 500 is placed on the DC terminal side of the electric circuit body 400. By setting the capacitor module in such a way as to match it in height to the electric circuit body 400, the power conversion device 200 can be reduced in thickness, which improves a degree of freedom in installation in a vehicle. The AC side terminal 325A of the electric circuit body 400 penetrates a current sensor 180 and is connected to the connector 188. The positive electrode terminal 325P and the negative electrode terminal 325M, which are the DC terminals of the semiconductor module 300, are joined to positive and negative electrode terminals 362A and 362B of the capacitor module 500, respectively.

The embodiments described above offer the following effects.

(1) The electric circuit body 400 includes: the semiconductor module 300 that includes the semiconductor elements 155, 156, 157, and 158 sealed with the sealing material 360 and that has a heat-dissipation surface on at least one surface, the heat dissipation surface dissipating heat generated by the semiconductor elements 155, 156, 157, and 158; the cooling member 340 disposed counter to the heat dissipation surface of the semiconductor module 300, the cooling member 340 cooling the semiconductor elements 155, 156, 157, and 158 that generate heat; and the fixing member 341 buried in the sealing material 360 of the semiconductor module 300, the fixing member 341 restricting movement of the cooling member 340 in the direction of separating away from the semiconductor module 300. The fixing member 341 includes the buried part 344 buried in the sealing material 360, and the fixing part 342 inserted into the cooling member 340 to fix the cooling member 340. At the boundary between the buried part 344 and the fixing part 342, the buried part 344 has the margin part 343 encircling the outer periphery of the fixing part 342 and exposed from the surface of the sealing material 360. With this configuration, outflow of the sealing material in the vicinity of the fixing member can be prevented.

(2) The method for manufacturing the electric circuit body 400 is the method for manufacturing the electric circuit body 400 which includes the semiconductor elements 155, 156, 157, and 158, the cooling member 340 that cools the semiconductor elements 155, 156, 157, and 158 that generate heat, and the fixing member 341 that fixes the cooling member 340 and in which the semiconductor elements 155, 156, 157, and 158 and the fixing member 341 are sealed with the sealing material 360. The fixing member 341 includes the buried part 344 buried in the sealing material 360, and the fixing part 342 inserted into the cooling member 340 to fix the cooling member 340. At the boundary between the buried part 344 and the fixing part 342, the buried part 344 has the margin part 343 encircling the outer periphery of the fixing part 342 and exposed from the surface of the sealing material 360. The method includes: a process of setting the circuit body 310 including the semiconductor elements 155, 156, 157, and 158 and the fixing member 341 in the mold 603, bringing the mold 603 into close contact with the margin part 343 of the fixing member 341, and then injecting the sealing material 360 into the mold 603 to manufacture the semiconductor module 300; and a process of fixing the cooling member 340 to the semiconductor module 300 by the fixing member 341 after the sealing material 360 cures. With this configuration, outflow of the sealing material in the vicinity of the fixing member can be prevented.

The present invention is not limited to the above embodiments. Other embodiments that can be conceived within a range of the technical concept of the present invention are also included in the scope of the invention, providing that such embodiments do not impair features of the present invention. A combination of the above-described embodiments and a plurality of modifications may also constitute the present invention.

### REFERENCE SIGNS LIST

10 upper case
11 lower case
13 refrigerant inflow pipe
14 refrigerant outflow pipe
17, 21, 181, 182, 188 connector
18 AC terminal
43, 140, 142 inverter circuit
155, 156, 157, 158 semiconductor element
172 control circuit
174 driver circuit
180 current sensor
192, 194 motor generator
200 power conversion device
300 semiconductor module
310 circuit body
325P positive electrode side terminal
325M negative electrode side terminal
325A AC side terminal
325C collector sense terminal
325L lower arm gate terminal
325E emitter sense terminal
325U upper arm gate terminal
340 cooling member
341 fixing member
342 fixing part
343 margin part
344 buried part
360 sealing material
400 electric circuit body
430, 431, 432, 433 conductor plate
440 insulating sheet
443 resin insulating layer
444 surface conductor layer
453 heat conduction member
500 capacitor module
601 transfer molding device
602 spring
603 mold

1. An electric circuit body comprising:
a semiconductor module that includes a semiconductor element sealed with a sealing material and that has a heat dissipation surface on at least one surface, the heat dissipation surface dissipating heat generated by the semiconductor element;
a cooling member disposed counter to the heat dissipation surface of the semiconductor module, the cooling member cooling the semiconductor element that generates heat; and
a fixing member buried in the sealing material of the semiconductor module, the fixing member restricting movement of the cooling member in a direction of separating away from the semiconductor module, wherein
the fixing member includes a buried part buried in the sealing material, and a fixing part inserted into the cooling member to fix the cooling member, and wherein
at a boundary between the buried part and the fixing part, the buried part has a margin part encircling an outer periphery of the fixing part and exposed from a surface of the sealing material.

2. The electric circuit body according to claim 1, wherein
a mold is brought into close contact with the margin part in a process of injecting the sealing material, and wherein
a material of the margin part is a material having hardness lower than hardness of the mold.

3. The electric circuit body according to claim 1, wherein
the margin part and a surface of the sealing material of the semiconductor module are on the same plane.

4. The electric circuit body according to claim 1, wherein
a material of the fixing part is a material having hardness higher than hardness of the margin part.

5. The electric circuit body according to claim 1, wherein
a periphery of the buried part is subjected to a surface treatment for adhesion to the sealing material.

6. The electric circuit body according to claim 1, wherein
the fixing member penetrates the semiconductor module in a direction of its thickness, and the margin part is formed on both ends of the fixing member.

7. The electric circuit body according to claim 1, wherein
the semiconductor module has the heat dissipation surfaces formed respectively on both surfaces of the semiconductor module such that the heat dissipation surfaces correspond to both surfaces of the semiconductor element, wherein
the cooling member is mounted on both surfaces of the semiconductor module, and wherein
the fixing member has the margin part that is disposed on the both surfaces and that is exposed from a surface of the sealing material against the cooling member.

8. A power conversion device comprising the electric circuit body according to claim 1, wherein
the power conversion device converts DC power into AC power and vice versa.

9. A method for manufacturing an electric circuit body which includes a semiconductor element, a cooling member that cools the semiconductor element that generates heat, and a fixing member that fixes the cooling member and in which the semiconductor element and the fixing member are sealed with a sealing material, wherein
the fixing member includes:
a buried part buried in the sealing material; and
a fixing part inserted into the cooling member to fix the cooling member, wherein
at a boundary between the buried part and the fixing part, the buried part has a margin part encircling an outer periphery of the fixing part and exposed from a surface of the sealing material, and wherein
the method comprises:
a process of setting a circuit body including the semiconductor element and the fixing member in a mold, bringing the mold into close contact with the margin part of the fixing member, and then injecting the sealing material into the mold to manufacture a semiconductor module; and
a process of fixing the cooling member to the semiconductor module by the fixing member after the sealing material cures.

10. The method for manufacturing the electric circuit body according to claim 9, wherein
in the process of manufacturing the semiconductor module, the margin part is deformed as a result of being clamped by the mold.
